(19) United States
(12) Patent Application Publication
(10) Pub. No.: US 2023/0158750 A1
(43) Pub. Date: May 25, 2023

(54) SYSTEMS AND METHODS OF CONTROL INSTRUCTIONS GENERATION AND INTERPRETATION IN ADDITIVE MANUFACTURING OF ELECTRONIC COMPONENTS

(71) Applicant: ABB Schweiz AG, Baden (CH)

(72) Inventors: Daniel Pierce Armstrong, Cary, NC (US); Matthew Hetrich, Cary, NC (US); Sheng Zhong, Raleigh, NC (US); Marius Rutkevicius, Raleigh, NC (US); Elio Alberto Perigo, Raleigh, NC (US)

(21) Appl. No.: 17/534,702

(22) Filed: Nov. 24, 2021

(51) Int. Cl. B29C 64/393; G06F 30/30; B41F 15/08

(52) U.S. Cl. CPC B29C 64/393; G06F 30/30; B41F 15/0813

(57) ABSTRACT

A system of additive manufacturing of an electronic component is provided. The system includes a deposition control computing device, the deposition control computing device including at least one processor in communication with at least one memory device. The at least one processor is programmed to generate control instructions of additive manufacturing of the electronic component, interpret the control instructions into controls of the system, and output the controls.

### BACKGROUND

The field of the disclosure relates to manufacturing of electronic components, and more particularly, to additive manufacturing of electronic components.

Different techniques are known to manufacture electronic components such as resistors or voltage dividers by applying a non-insulating, electrically resistive film or foil material onto an insulating substrate. Typical methods are sputtering (thin film) or screen and stencil printing (thick film).

Known systems and methods of manufacturing electronic components are disadvantaged in some aspects and improvements are desired.

### BRIEF DESCRIPTION

In one aspect, a system of additive manufacturing of an electronic component is provided. The system includes a deposition control computing device, the deposition control computing device including at least one processor in communication with at least one memory device. The at least one processor is programmed to generate control instructions of additive manufacturing of the electronic component, interpret the control instructions into controls of the system, and output the controls.

In another aspect, a system of additive manufacturing of an electronic component is provided. The system includes a deposition control computing device, the deposition control computing device including at least one processor in communication with at least one memory device. The at least one processor is programmed to receive, in a user interface, user inputs, generate control instructions of additive manufacturing of the electronic component based on the user inputs, and output the control instructions.

In one more aspect, a system of additive manufacturing of an electronic component is provided. The system includes a deposition control computing device, the deposition control computing device including at least one processor in communication with at least one memory device. The at least one processor is programmed to interpret control instructions of manufacturing the electronic component into controls of the system by interpreting the control instructions into fundamental actions in the system and output the controls.

### DRAWINGS

Non-limiting and non-exhaustive embodiments are described with reference to the following Figures., wherein like reference numerals refer to like parts throughout the various drawings unless otherwise specified.

FIG. 1A is a schematic diagram of an exemplary system of additive manufacturing.

FIG. 1B is a schematic diagram of an exemplary disposition assembly of the system shown in in FIG. 1A.

FIG. 1C is a schematic diagram of a deposition control computing device of the deposition assembly shown in FIG. 1B.

FIG. 2A is a flow chart of an exemplary control instruction generator of the deposition control computing device shown in FIG. 1C.

FIG. 2B is an exemplary user interface to receive user inputs for generating control instructions.

FIG. 3 is a block diagram of an exemplary user interface of an exemplary control instruction interpreter of the deposition control computing device shown in FIG. 1C.

FIG. 4 shows exemplary voltage dividers manufactured using systems and methods shown in FIGS. 1A-3.

FIG. 5 is a schematic diagram of a user computing device.

### DETAILED DESCRIPTION

The disclosure includes systems and methods of additive manufacturing of electronic components such as resistors or voltage dividers. Method aspects will be in part apparent and in part explicitly discussed in the following description.

In manufacturing electronic components such as resistors or voltage dividers, the process includes depositing a film onto a substrate, baking the deposition with the substrate in a high temperature furnace such as over 500° C., and trimming the resistive path to fine-tune the electronic component. During deposition, a non-insulating, electrically resistive film or foil material, such as metal film or metal foil, e.g., nickel chromium, cermet film, e.g., tantalum nitride, ruthenium dioxide, bismuth ruthenate, carbon film, or a film of composite material based on a mixture of glass and cermet is deposited onto an insulating or dielectric substrate. The insulating substrate may be ceramic, silicon, glass or other synthetic material. In addition, highly conductive structures with considerable lower resistivity than the film material of the resistors are deposited on the substrate as well. The highly conductive structures are intended to be used as contacting terminals, and they are placed on the substrate in such a way that the resistive film material of the resistors overlaps partly with them.

Film material may be applied to the substrate by known methods such as sputtering or screen printing. Sputtering is not suitable for manufacturing resistors having a high resistance value (e.g., 20 M ohm or greater), voltage dividers having a high voltage ratio, or components in high voltage sensors. Screen printing therefore is typically used. Screen printing allows for reasonably high throughput on complex circuit shapes such as those in non-inductive high voltage resistors and other integrated circuits. Screen printing process, however, is inflexible. Screen printing requires a screen or mask to be generated. For low volume parts and circuit designs, it is prohibitively costly to operate a manufacturing line for screen printing for small orders and custom designs. Current suppliers of resistors for high voltage and high power devices have long lead times, such as weeks or even months for standard designs and longer for custom orders. Some custom and complex resistors having features such as voltage cushions, integrated voltage dividers, or non-typical resistance values have even longer lead times.

In contrast, an additive manufacturing method offers a high degree of design flexibility whiles still providing relatively high throughput. With additive methods, increased complexity does not require an increase in production cost. Rather than designing screens, the systems and methods disclosed herein provide automatic and flexible generation of control instructions and control of the additive manufacturing of electronic components. Systems and methods described herein provide a low cost printer with multiple movement stages, motors and control system that drastically reduces lead time to a time frame for example less than three days, allows for rapid prototyping of new designs, increases automation, and reduces the overall part count in printing integrated circuits.

Compared to screen-printing, one more advantage of additive manufacturing is that deposition patterns in additive manufacturing are not limited by the screen. In screen-printing, because a screen is required, screen-printing cannot print a pattern having a complete loop that encompasses a circumference of a three-dimensional (3D) substrate such as a cylindrical substrate, limiting designs of electronic components.

In conventional additive manufacturing of an object, multiple layers are used, each layer having a thickness of the level of at least several micrometers, with final part having millimeters to meters in at least one dimension. Further, typically the control codes of manufacturing the object requires input of a finalized 3D design of the object and the generation process is not modular, where similar or same features are designed separately repeatedly.

In contrast, in additive manufacturing of electronic components, especially high voltage electronic components, a single layer is typically used and the thickness of each layer is in the order of μm. Systems and methods described herein allow a user to provide properties of an electronic component and generate a deposition design of the electronic component that has the properties, instead of requiring a final 3D design of the electronic component. In addition, systems and methods described herein use a modular design, where similar or same features are design once and then adjusted based on parameters or properties of the electronic components, thereby increasing the efficiency of the process.

Furthermore, systems and methods described herein include generating instructions that instruct robot(s) to operate the printer to improve resistor placement reproducibility between different operators, different manufacturing sites, and resistor substrates originating from different suppliers.

Compared to conventional manufacturing of an electrical component, systems and methods described herein are advantageous in manufacturing high voltage electrical components, such as high voltage dividers. In conventional manufacturing of a voltage divider, resistors of the divider and their connections are separately designed and manufactured. Systems and methods described herein provide design flexibility, save space for electrical components, and provide uniform form factors for electrical components. For example, resistors and their connections are included one deposition design on one substrate.

Systems and methods described herein provide rapid prototyping and custom circuit designs, where deposition patterns are quickly generated based on user inputs. Creating a new drawing for each pattern and going through various iterations on the design is time consuming for an engineer. Systems and methods described herein automates the design process and converts the design into machine code for the actuator controllers for fast prototyping. Robotic integration offers integration of the technology across multiple sites with or without personnel training in the field of resistor handling throughout the printing process, offering reduction in sample-to-sample and site-to-site variability, as well as streamlined resources available on a 24/7 basis.

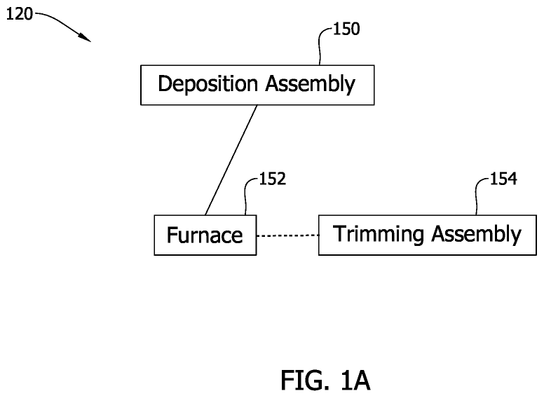

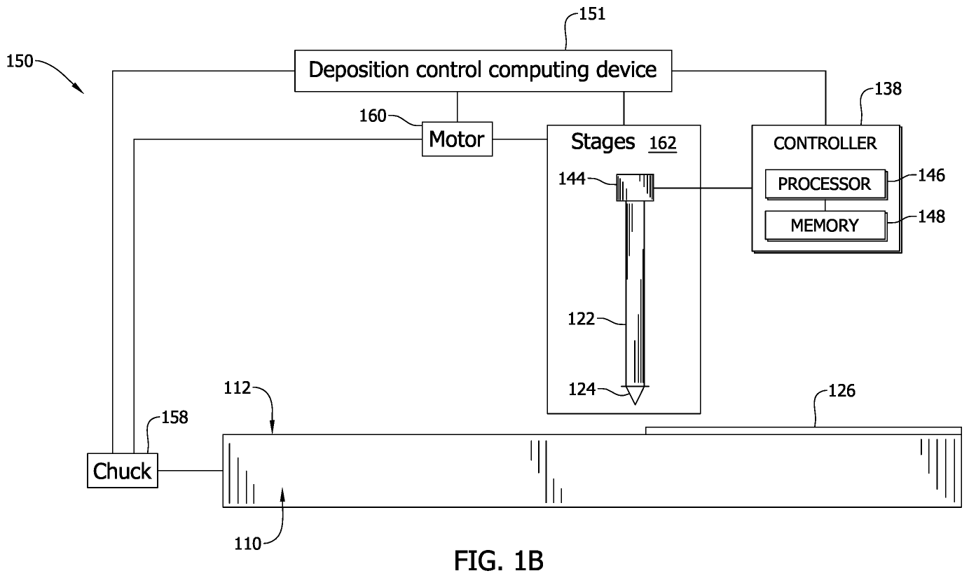

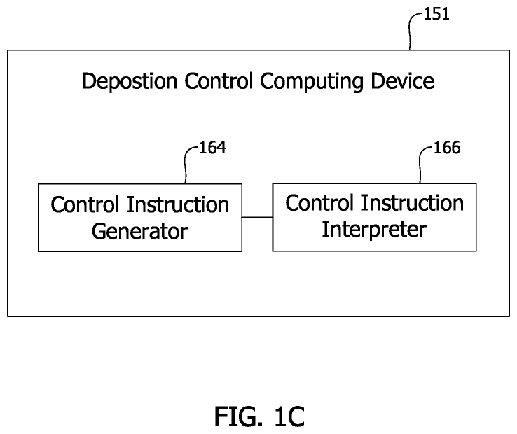

FIG. 1A-1C are a schematic diagram of an exemplary system 120 of additive manufacturing of an electronic component (FIG. 1A), a schematic diagram of an exemplary deposition assembly or printer 150 of system 120 (FIG. 1B), and a schematic diagram of an exemplary deposition control computing device 151 used to control deposition assembly 150 (FIG. 1C). The electronic component may be a high voltage electronic component such as a high voltage divider. The voltage of the electronic component may be 3.6 kV or above. Alternatively, the resistance ratio of the voltage divider is greater than 1000:1, or even greater than 10,000:1. The electronic component may be a resistor or a voltage divider, which may be used in a voltage sensor. In the exemplary embodiment, the system 120 includes a deposition assembly 150 configured to deposit an additive material 126 onto a substrate 110 (FIG. 1B), and a furnace 152 used to bake the printed components. System 120 may include a trimming assembly 154. The systems and methods described herein, however, do not require a trimming assembly 154.

Additive manufacturing is applied to a substrate 110. For example, substrate 110 is configured to form a voltage divider for use in a high voltage sensor. Substrate 110 is generally a dielectric substrate, e.g. a ceramic material or plastic, that does not conduct electricity. Substrate 110 includes a surface 112 that is configured to receive an additive material, such as a conductive material or a resistive paste that is applied using additive manufacturing. In some embodiments, surface 112 is non-planar. For example, substrate 110 is generally cylindrical in shape.

In the exemplary embodiment, deposition assembly 150 of system 120 includes a dispenser 122 and an actuator 144. A dispenser may also be referred to as a dispensing needle. Dispenser 122 may be a pneumatic dispenser, a syringe pump dispenser, or other dispensing devises configured to dispense a material having a high viscosity, e.g., greater than 1000 centipoise. The dispenser includes a dispensing tip 124. The size of tip 124 may be in the range of approximately 100-2000 μm, or 250-1000 μm. Tip 124 of dispenser 122 is moved along surface 112 of substrate 110 to apply an additive material 126 to surface 112.

In the exemplary embodiment, deposition assembly 150 further includes a chuck 158, a motor 160, stages 162, and a deposition control computing device 151. Chuck 158 may be a rotary chuck that holds substrate 110 and rotates substrate 110 during printing. Motor 160 provides movement of chuck and stages. Motor 160 may be a motor assembly that includes a plurality of motors. Stages 162 may be three linear moveable stages along three axes x, y, and z. Dispenser 122 is coupled to stages 162 such that positions and movements of dispenser 122 is adjusted or controlled. Deposition control computing device 151 is in communication with chuck, motor, stages, and a controller 138 of actuator 144 and controls operation of deposition assembly 150. Deposition control computing device 151 may be a user computing device, a processor-based microcontroller, or a combination of both.

Deposition assembly 150 may further include controller 138 in communication with actuator 144. In some embodiments, controller 138 includes a processor-based microcontroller including a processor 146 and a memory device 148 wherein executable instructions, commands, and control algorithms, as well as other data and information needed to satisfactorily operate system 120, are stored. Memory 148 includes instructions that when executed by processor 146 enable controller 138 to control actuator 144, which in turn controls the movement and positions of Dispenser 122. In some embodiments, memory device 148 may be, for example, a random access memory (RAM), and other forms of memory used in conjunction with RAM memory, including but not limited to flash memory (FLASH), programmable read only memory (PROM), and electronically erasable programmable read only memory (EEPROM).

As used herein, the term “processor-based” microcontroller shall refer not only to controller devices including a processor or microprocessor as shown, but also to other equivalent elements such as microcomputers, programmable logic controllers, reduced instruction set circuits (RISC), application specific integrated circuits and other programmable circuits, logic circuits, equivalents thereof, and any other circuit or processor capable of executing the functions described below. The processor-based devices listed above are exemplary only, and are thus not intended to limit in any way the definition and/or meaning of the term “processor-based.”

In the exemplary embodiment, deposition assembly 150 is controlled by deposition control computing device 151. Deposition control computing device 151 includes a control instruction generator 164 configured to convert a circuit design into control codes or instructions and a control instruction interpreter 166 configured to interpret control instructions into controls of deposition assembly 150. Control instructions may be in G-Code, which is a language used to describe how a machine will move to accomplish a given task, using numerical control of machining tools such as additive printers. In some embodiments, control instructions are drawings of a deposition design for manufacturing the electronic component. The controls may be instructions downloaded or control signals transmitted to controller 138. Deposition control computing device 151 may be two separate computing devices with control instruction generator 164 in one computing device and control instruction interpreter 166 in another computing device. Alternatively, control instruction generator 164 and control instruction interpreter 166 are in the same computing device.

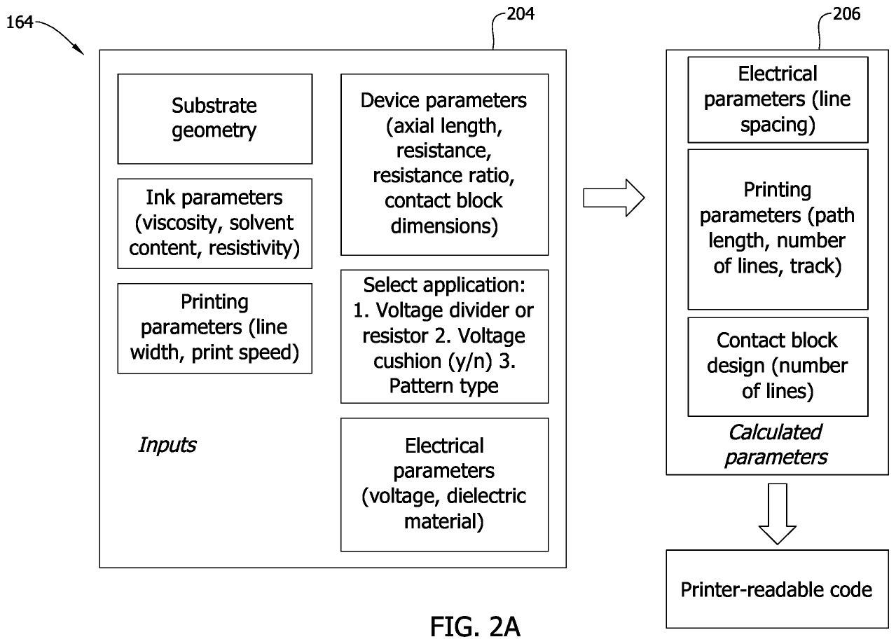

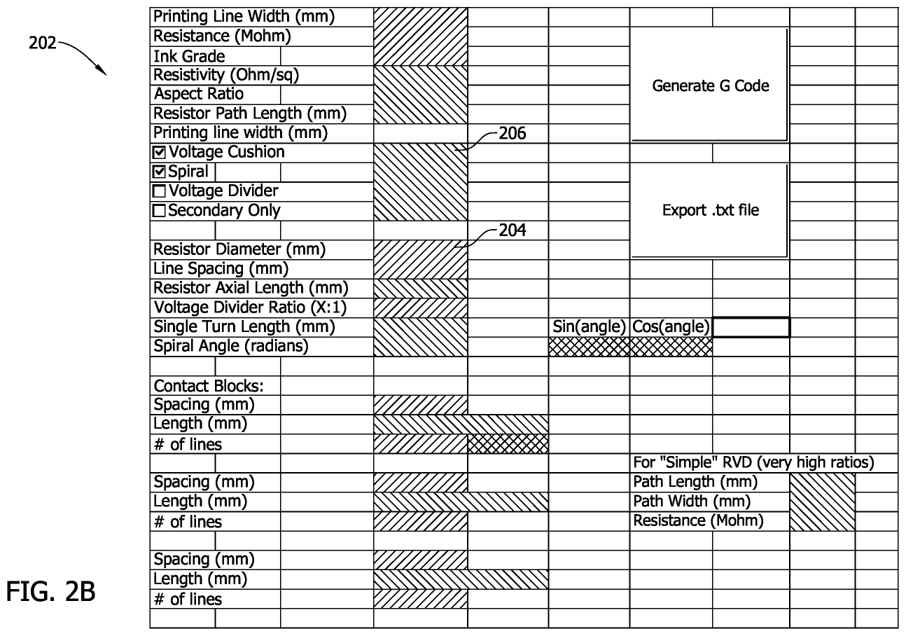

FIGS. 2A and 2B show control instruction generator 164. FIG. 2A is a flow chart of generating control instructions implemented in control instruction generator 164. FIG. 2B is an exemplary user interface 202 of control instruction generator 164.

In the exemplary embodiment, control instruction generator 164 provides automated path generation for designing resistor paths from user inputs. Control instruction generator 164 is configured to take user inputs on desired device parameters such as, but not limited to, a voltage rating, power rating, primary side resistance value, and voltage divider ratio. The inputs set the parameters of the deposition design to be physically realized by deposition assembly 150. In control instruction generator 164, physical models and preset general path structures (e.g. non-inductive paths) are used to generate a printing path defined by G code commands readable by a microcontroller. Physical modes may be based on the physical or empirical relations of physical and electronical properties with geometrical designs of the electronic components. In some embodiments, a machine learning model or a combination of a machine learning model and a physical model may be used in designing deposition patterns. Control instruction generator 164 may also generate spiral and/or non-inductive patterns. Resistive path designs using systems and methods described herein leverage the flexibility of additive manufacturing.

In the exemplary embodiment, inputs may include substrate geometry, ink parameters (e.g., viscosity, solvent content, and resistivity of the ink), printing parameters (e.g., line width and printing speed), device parameters or parameters of the electronic component (e.g., axial length, resistance, resistance ratio of a voltage divider, dimensions of a contact block, a voltage rating, a power rating, or a primary side resistance value), application selections (e.g., voltage divider or resistor, whether to include a voltage cushion, and the type of pattern), electrical parameters (e.g., voltage and dielectric material), and any combination thereof. Control instruction interpreter is configured to calculate parameters based on the inputs 204 to provide calculated parameters 206 such as electrical parameters (e.g., line spacing), printing parameters (e.g., path length, number of lines, and track), contact block design (e.g., number of lines), and any combination thereof. Based on the inputs 204 and calculated parameters 206, control instruction generator 164 provides printer-readable codes such as G-Codes. In some embodiments, control instruction generator 164 is configured to receive a technical drawing of circuit designs, such as a CAD drawing or a circuit diagram, as inputs and convert the technical drawings into modular features, G-codes, and/or or deposition designs, thereby obviating the need of manually inputting properties of the electrical component. In one embodiment, control instruction generator is configured to output a deposition design corresponding to the circuit design. In another embodiment, each pattern includes fundamental actions adapted based on input parameters. In one example, part of the scripts are written in Visual Basic® that draws input information from a spreadsheet. The output control code may be in G-Code. The output G-Code is exported to a text file that may be read in by control instruction interpreter 166. In one example, control instruction generator 164 is configured to take user inputs on properties of a circuit such as resistance, inductance, and impedance, and generate G-Codes for a deposition design that matches the input properties. Control instruction generator 164 may output calculated features or parameters 206 in user interface 202 such that the user may examine the design.

In the exemplary embodiment, control instruction generator 164 includes a set of scripts that translate user inputs 204 (FIG. 2B) such as ink and substrate information, voltage rating, part size, resistance value, ratios between resistances into modular commands that provide spatial directions for control instruction interpreter 166. Modules are for particular types of patterns, and specific features of the pattern are modified by user inputs. For example, modules may include contact areas for electrical terminals, high aspect ratio traces for high resistance sections, serpentine paths for non-inductive resistors, trimming such as laser trimming tuning, and tapered paths for impulse cushioning. If a user inputs include impulse cushioning, the inputs are used in the module of tapered paths for impulse cushioning. In another example, the modules include variable parameters such as area, length, or the number of repeated features. This list is not comprehensive. New features may be added in by creating new modules.

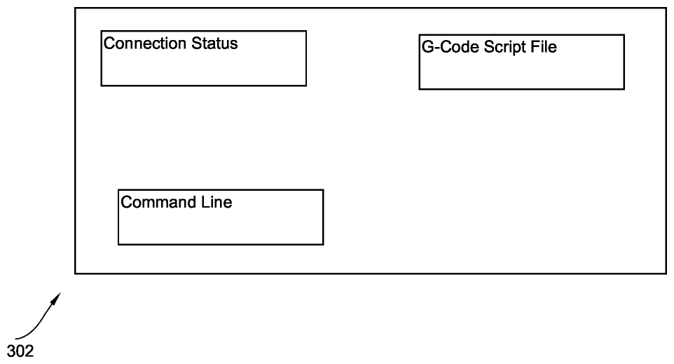

FIG. 3 is a block diagram of an exemplary interface 203 of control instruction interpreter 166, which provides controls of a microcontroller and deposition assembly 150. In the exemplary embodiment, top left of interface 203 shows connection status to hardware. Top right of interface 203 shows a preview of the G-Code text file that is uploaded to deposition assembly 150. Bottom left of interface 203 provides input for a command line, which is direct interfacing between the user and deposition assembly 150. Control instruction interpreter 166 reads in a text file with G-Code commands and convert G-Codes to controls of system 120, such as control signals of a series of actuators 144. Control instruction interpreter 166 may be personal computer (PC) software. In some embodiments, the control instruction interpreter 166 is configured to read in drawing files of deposition patterns or designs and interpret the drawings into control signals of system 120. The actuators may be linear micro-stepped stages, a micro-stepped rotational stage, liquid dispensing devices, and piezoelectric linear stages. This list is not exhaustive, and other actuators may be added to the printer hardware under the same control schema. The controls are transmitted to microcontroller 138. Firmware of controller 138 co-ordinates movement speed of various actuator components to ensure a constant movement speed of the dispensing head of deposition assembly 150. Control instruction interpreter 166 achieves those functions by interpreting the incoming commands and translating the commands into corresponding electrical signals or control signals that the motor drivers need for simultaneous, multi-axis movement. The commands may be broken down into fundamental actions that act as the building blocks of every pattern. Fundamental actions include but are not limited to linear movements, clockwise/counter-clockwise arcing, and dispensing/non-dispensing movements. The firmware of controller 138 and/or control instruction interpreter 166 may take in parameters of the geometry of the starting substrate and properties of the dispensing fluid and adapt the fundamental commands accordingly. Control instruction interpreter 166 is also configured to receive direct input from the printer user to monitor print conditions, clear memory, and other functions (see FIG. 3). Control instruction interpreter 166 may be modified to include additional features such as changing movement speed of the print head as defined by the user.

In some embodiments, deposition control computing device 151 is configured to automate the deposition. For example, deposition control computing device 151 is configured to remove the need of manual installation, removal, and alignment of the resistor rod or substrate 110 in the printer chuck 158. In this embodiment, software for robotic control is included in addition to the software described above. The functions of the software include picking and installing a new resistor rod into a chuck-coupled robotic arm, moving the robotic arm to the correct radial location such that the rod is at the desired needle position, moving the robotic arm to the desired axial position of the printing start, providing rotational and axial movement of the chuck with robotic arm as per G-Code described above, placing the printed resistor into a drying oven and releasing the printed resistor from the chuck.

In the exemplary embodiment, two separate interfaces are used for control instruction generator 164 for the circuit generation (FIG. 2B) and control instruction interpreter 166 for the controls (FIG. 3). In one example, the PC interface uses a C# Windows Forms Designer GUI for input, and the generation tool uses Active X controls within the input spreadsheet. In some embodiments, the circuit design and controller interfaces are integrated as one interface.

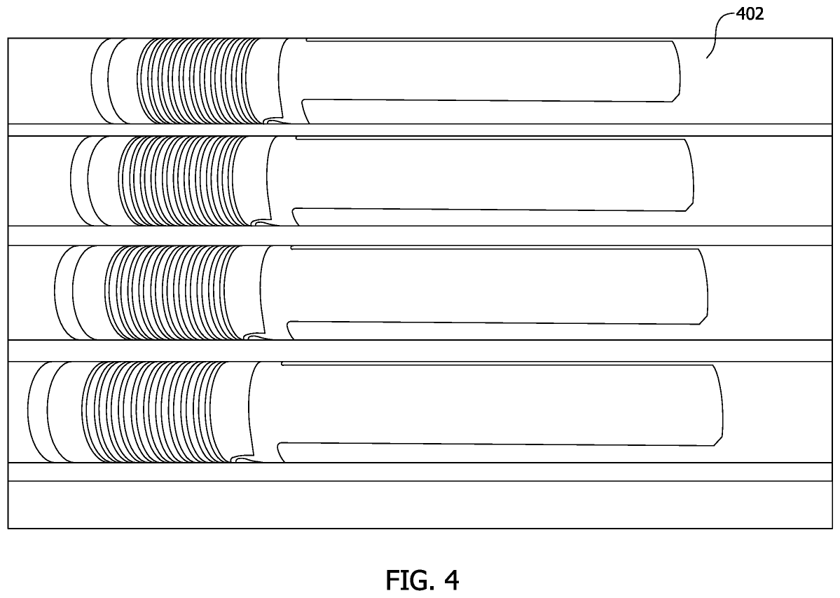

FIG. 4 shows voltage dividers 402 manufactured using systems and methods described herein. Printed resistive voltage dividers 402 have a high aspect ratio primary resistive path, and a low aspect ratio secondary path. Line widths (i.e. print resolution) of 300-800 microns have been generated, though larger line widths are clearly possible. Deposition assembly 150 has generated prints of resistors with resistance values as high as 50 MOhm, and higher resistances up to at least 5 GOhms are feasible. Printed path lengths may be at 1.6 meters with an aspect ratio of as high as 4000:1. Additionally, overlapping printed paths have been generated to create large printed areas with low aspect ratios.

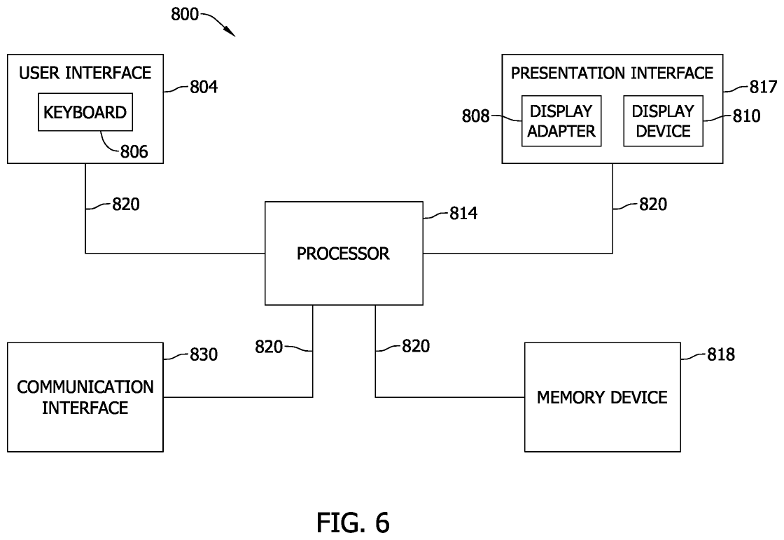

Deposition control computing device 151 described herein may be any suitable user computing device 800 and software implemented therein. FIG. 5 is a block diagram of an exemplary computing device 800. In the exemplary embodiment, the computing device 800 includes a user interface 804 that receives at least one input from a user. The user interface 804 may include a keyboard 806 that enables the user to input pertinent information. The user interface 804 may also include, for example, a pointing device, a mouse, a stylus, a touch sensitive panel (e.g., a touch pad and a touch screen), a gyroscope, an accelerometer, a position detector, and/or an audio input interface (e.g., including a microphone).

Moreover, in the exemplary embodiment, computing device 800 includes a presentation interface 817 that presents information, such as input events and/or validation results, to the user. The presentation interface 817 may also include a display adapter 808 that is coupled to at least one display device 810. More specifically, in the exemplary embodiment, the display device 810 may be a visual display device, such as a cathode ray tube (CRT), a liquid crystal display (LCD), a light-emitting diode (LED) display, and/or an “electronic ink” display. Alternatively, the presentation interface 817 may include an audio output device (e.g., an audio adapter and/or a speaker) and/or a printer.

The computing device 800 also includes a processor 814 and a memory device 818. The processor 814 is coupled to the user interface 804, the presentation interface 817, and the memory device 818 via a system bus 820. In the exemplary embodiment, the processor 814 communicates with the user, such as by prompting the user via the presentation interface 817 and/or by receiving user inputs via the user interface 804. The term “processor” refers generally to any programmable system including systems and microcontrollers, reduced instruction set computers (RISC), complex instruction set computers (CISC), application specific integrated circuits (ASIC), programmable logic circuits (PLC), and any other circuit or processor capable of executing the functions described herein. The above examples are exemplary only, and thus are not intended to limit in any way the definition and/or meaning of the term “processor.”

In the exemplary embodiment, the memory device 818 includes one or more devices that enable information, such as executable instructions and/or other data, to be stored and retrieved. Moreover, the memory device 818 includes one or more computer readable media, such as, without limitation, dynamic random access memory (DRAM), static random access memory (SRAM), a solid state disk, and/or a hard disk. In the exemplary embodiment, the memory device 818 stores, without limitation, application source code, application object code, configuration data, additional input events, application states, assertion statements, validation results, and/or any other type of data. The computing device 800, in the exemplary embodiment, may also include a communication interface 830 that is coupled to the processor 814 via the system bus 820. Moreover, the communication interface 830 is communicatively coupled to data acquisition devices.

In the exemplary embodiment, the processor 814 may be programmed by encoding an operation using one or more executable instructions and providing the executable instructions in the memory device 818. In the exemplary embodiment, the processor 814 is programmed to select a plurality of measurements that are received from data acquisition devices.

In operation, a computer executes computer-executable instructions embodied in one or more computer-executable components stored on one or more computer-readable media to implement aspects of the invention described and/or illustrated herein. The order of execution or performance of the operations in embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

As used herein, the terms “processor” and “computer,” and related terms, e.g., “processing device,” “computing device,” and “controller” are not limited to just those integrated circuits referred to in the art as a computer, but broadly refers to a microcontroller, a microcomputer, an analog computer, a programmable logic controller (PLC), an application specific integrated circuit (ASIC), and other programmable circuits, and these terms are used interchangeably herein. In the embodiments described herein, “memory” may include, but is not limited to, a computer-readable medium, such as a random-access memory (RAM), a computer-readable non-volatile medium, such as a flash memory. Alternatively, a floppy disk, a compact disc—read only memory (CD-ROM), a magneto-optical disk (MOD), and/or a digital versatile disc (DVD) may also be used. Also, in the embodiments described herein, additional input channels may be, but are not limited to, computer peripherals associated with an operator interface such as a touchscreen, a mouse, and a keyboard. Alternatively, other computer peripherals may also be used that may include, for example, but not be limited to, a scanner. Furthermore, in the example embodiment, additional output channels may include, but not be limited to, an operator interface monitor or heads-up display. Some embodiments involve the use of one or more electronic or computing devices. Such devices typically include a processor, processing device, or controller, such as a general purpose central processing unit (CPU), a graphics processing unit (GPU), a microcontroller, a reduced instruction set computer (RISC) processor, an ASIC, a programmable logic controller (PLC), a field programmable gate array (FPGA), a digital signal processing (DSP) device, and/or any other circuit or processing device capable of executing the functions described herein. The methods described herein may be encoded as executable instructions embodied in a computer readable medium, including, without limitation, a storage device and/or a memory device. Such instructions, when executed by a processing device, cause the processing device to perform at least a portion of the methods described herein. The above examples are not intended to limit in any way the definition and/or meaning of the term processor and processing device.

At least one technical effect of the systems and methods described herein includes (a) additive manufacturing of high-voltage electronic components; (b) generating circuit designs based on user inputs; (c) generating deposition designs based on properties of the electronic component, rather than a finalized design of the electronic component; and (d) modular design of features.

Exemplary embodiments of systems and methods of additive manufacturing of electronic components are described above in detail. The systems and methods are not limited to the specific embodiments described herein but, rather, components of the systems and/or operations of the methods may be utilized independently and separately from other components and/or operations described herein. Further, the described components and/or operations may also be defined in, or used in combination with, other systems, methods, and/or devices, and are not limited to practice with only the systems described herein.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A system of additive manufacturing of an electronic component, comprising a deposition control computing device, the deposition control computing device comprising at least one processor in communication with at least one memory device, and the at least one processor programmed to:
generate control instructions of additive manufacturing of the electronic component;
interpret the control instructions into controls of the system; and
output the controls.

2. The system of claim 1, wherein the at least one processor is further programmed to:
generate, in modules, the control instructions of additive manufacturing of the electronic component.

3. The system of claim 2, wherein the modules include at least one of contact areas of electrical terminals, high aspect ratio traces, serpentine paths of non-inductive resistors, trimming, or tapered paths of impulse cushioning.

4. The system of claim 1, wherein the at least one processor is further programmed to:
receive user inputs; and
generate the control instructions based on the user inputs.

5. The system of claim 4, wherein the user inputs include at least one of substrate geometry, an ink parameter, a printing parameter, a parameter of the electronic component, an application selection, or an electrical parameter.

6. The system of claim 5, wherein the parameter of the electronic component includes at least one of a voltage rating, a power rating, a primary side resistance value, or a voltage divider ratio.

7. The system of claim 1, wherein the at least one processor is further programmed to:
receive a drawing of a circuit design; and
generate the control instructions based on the drawing.

8. The system of claim 1, wherein the at least one processor is further programmed to:
interpret the control instructions into commands of fundamental actions.

9. The system of claim 1, wherein the at least one processor is further programmed to:
generate control instructions of at least one of a robotic arm or a chuck of the system.

10. A system of additive manufacturing of an electronic component, comprising a deposition control computing device, the deposition control computing device comprising at least one processor in communication with at least one memory device, and the at least one processor programmed to:
receive, in a user interface, user inputs;
generate control instructions of additive manufacturing of the electronic component based on the user inputs; and
output the control instructions.

11. The system of claim 10, wherein the at least one processor is further programmed to:
generate, in a plurality of modules, control instructions of additive manufacturing of the electronic component.

12. The system of claim 11, wherein the modules include at least one of contact areas of electrical terminals, high aspect ratio traces, serpentine paths of non-inductive resistors, trimming, or tapered paths of impulse cushioning.

13. The system of claim 10, wherein the user inputs include at least one of substrate geometry, an ink parameter, a printing parameter, a parameter of the electronic component, an application selection, or an electrical parameter.

14. The system of claim 13, wherein the parameter of the electronic component includes at least one of a voltage rating, a power rating, a primary side resistance value, or a voltage divider ratio.

15. The system of claim 10, wherein the at least one processor is further programmed to:
receive a drawing of a circuit design; and
generate the control instructions based on the drawing.

16. The system of claim 10, wherein the at least one processor is further programmed to:
output a drawing of a deposition design of the electronic component.

17. A system of additive manufacturing of an electronic component, comprising a deposition control computing device, the deposition control computing device comprising at least one processor in communication with at least one memory device, and the at least one processor programmed to:
interpret control instructions of manufacturing the electronic component into controls of the system by interpreting the control instructions into fundamental actions in the system; and
output the controls.

18. The system of claim 17, wherein the fundamental actions include at least one of a linear movement, a clockwise or counter-clockwise arcing, or a dispensing or non-dispensing movement.

19. The system of claim 17, wherein the at least one processor is further programmed to:
read in a drawing of a deposition design of manufacturing the electronic component; and
interpret the drawing into the controls of the system.

20. The system of claim 17, wherein the at least one processor is further programmed to:
receive user inputs of operation of the system; and
modify the controls based on the user inputs.
